(19) United States
(12) Patent Application Publication
(10) Pub. No.: US 2016/0298237 A1
(43) Pub. Date: Oct. 13, 2016

(54) PLASMA ELECTRODE, PLASMA PROCESSING ELECTRODE, CVD ELECTRODE, PLASMA CVD DEVICE, AND METHOD FOR MANUFACTURING SUBSTRATE WITH THIN FILM

(71) Applicant: TORAY INDUSTRIES, INC., Tokyo (JP)

(72) Inventors: Mamoru Kawashita, Otsu-shi, Shiga (JP); Hiroe Ejiri, Otsu-shi, Shiga (JP)

(73) Assignee: TORAY INDUSTRIES, INC., Tokyo (JP)

(21) Appl. No.: 15/038,207

(22) PCT Filed: Nov. 12, 2014
(86) PCT No.: PCT/JP2014/079940

§ 371 Date: May 20, 2016

(30) Foreign Application Priority Data
Nov. 22, 2013 (JP) 2013-241641

(51) Int. Cl. C23C 16/50

(52) U.S. Cl. CPC C23C 16/50

(57) ABSTRACT

The present invention relates to a plasma electrode including: an electrode main body having a discharge surface on the outer circumference surface thereof, the interior of the electrode main body having a magnet disposed therein for forming a tunnel-shaped magnetic field on the discharge surface; and ground members which face at least a portion of the discharge surface with a gap therebetween and face each other so as to sandwich the electrode main body therebetween. The discharge surface surrounds the outer circumference of the electrode main body, either with or without a gap interposed therebetween.

### CROSS REFERENCE TO RELATED APPLICATIONS

This is the U.S. National Phase application of PCT International Application No. PCT/JP2014/079940, filed Nov. 12, 2014, and claims priority to Japanese Patent Application No. 2013-241641, filed Nov. 22, 2013, the disclosures of each of these applications being incorporated herein by reference in their entireties for all purposes.

### FIELD OF THE INVENTION

Our invention relates to plasma electrode, plasma processing electrode and CVD electrode used for surface treatment and film deposition on the substrate.

### BACKGROUND OF THE INVENTION

It is generally known that surfaces of substrates can be reformed with plasma and that function film can be formed on the surface of substrates with a film depositing means using plasma. To provide plasma used for these technologies, various plasma electrodes have been developed and put into practical use. From a viewpoint of efficiency, the electrode technology for generating plasma on both sides of an electrode has been developed.

Patent document 1 discloses an electrode having two magnetic circuits back to back to generate plasma on both sides of the electrode so that a sputtering film deposition can be performed on both sides at the same time. With this technology, the sputtering film deposition can be performed on both sides of cathode comprising two cathodes integrated back to back, and the film deposition can be performed efficiently by feeding substrates in each film depositing zone.

Patent document 2 discloses an electrode structure having a magnetic circuit without yokes to generate magnetic field at both sides of the electrode for magnetron electric discharge. With this electrode, sputtering film deposition can be performed on both sides of cathode. This electrode doesn't have a yoke so that the magnetic flux density is distributed equally at the electric discharge surface side and its opposite side although conventional one has a yoke to induce the magnetic flux at the opposite side. This electrode makes it possible to perform two passes of sputtering film deposition per one electrode because another target surface can be provided at the opposite side of the electric discharge surface side to perform sputtering film deposition on both sides.

Patent document 3 discloses an electrode structure having a magnet unit to generate magnetic field at both sides for magnetron electric discharge so that sputtering film deposition can be performed on both sides of cathode. With this electrode having a magnetic circuit with a yoke to actively induce the magnetic flux for optimizing the magnetic flux density distribution, sputtering film deposition can be performed on both sides of cathode in the same way as in Patent document 2.

### PATENT DOCUMENTS

Patent document 1: JP2004-27272-A
Patent document 2: JP2006-233240-A
Patent document 3: JP2009-127109-A

### SUMMARY OF THE INVENTION

Patent documents 1-3 have suggested sputtering electrodes having an electrode structure capable of generating plasma on both sides of cathode for efficient sputtering film deposition. However, there hasn't been any efficient plasma source suggested suitably for a use such as plasma processing and plasma CVD, other than the sputtering film deposition. When the sputtering electrodes disclosed in Patent documents 1-3 are used for plasma processing or plasma CVD, generated plasma might have different intensities between both sides of cathode or plasma might be generated on one side only, and therefore electric discharge might not be achieved stably and equally on both sides. Although that may not be a big problem on a sputtering device to form one layer of film on one electric discharge surface, it could cause a poor controllability, on a plasma processing or plasma CVD electrode which generates two kinds of plasma for a single processing.

To solve the above-described problem, our plasma electrode comprises an electrode main body and ground members, the electrode main body having a discharge surface on an outer circumference surface thereof and a magnet disposed therein for forming a tunnel-shaped magnetic field on the discharge surface, the ground members facing at least a portion of the discharge surface with a gap therebetween and facing each other so as to sandwich the electrode main body therebetween, the discharge surface surrounding the outer circumference surface of the electrode main body, either with or without a gap interposed therebetween.

To solve the above-described problem, our plasma processing electrode comprises said plasma electrode and a gas nozzle introducing a gas in a direction parallel to the electric discharge surface into an electric discharge space between the ground member and the electric discharge surface facing the ground member.

Our CVD electrode comprises said plasma processing electrode and a source gas nozzle introducing a CVD source gas into a neighborhood of the electrode main body, wherein a film is deposited on a substrate placed in a position which is distant from the electrode main body and is downstream in a flow direction of the gas discharged from the gas nozzle.

Our plasma CVD device comprises said CVD electrode and a supporting mechanism of the substrate in a vacuum chamber.

Our manufacturing process of a substrate with a thin film comprises: a plasma generation step to generate a plasma with the plasma electrode of said CVD electrode; a gas feeding step to resolve the gas introduced through the plasma from the gas nozzle and feed a radical generated onto the substrate; a CVD source gas feeding step to feed the CVD source gas introduced from the source gas nozzle onto the substrate to form a thin film on the substrate.

Our invention can provide a plasma source efficient in terms of installation space and productivity to achieve high-speed plasma processing and plasma CVD film deposition relative to conventional technologies.

### BRIEF DESCRIPTION OF THE DRAWINGS

FIG. 1 is a schematic section view showing an example of plasma electrode of our invention, in which ground members are not shown.

FIG. 2 is a schematic section view showing another example of plasma electrode of our invention, in which ground members are not shown.

FIG. 3 is a schematic section view showing yet another example of plasma electrode of our invention, in which ground members are not shown.

FIG. 4a is a schematic section view showing an example of plasma processing electrode having a plasma electrode of our invention.

FIG. 4b is a schematic section view showing another example of plasma processing electrode having a plasma electrode of our invention.

FIG. 5 is a schematic diagram showing the section viewed in I-I arrow direction of the plasma processing electrode shown in FIG. 4a.

FIG. 6a is a schematic section view showing an example of plasma CVD electrode having a plasma processing electrode of our invention.

FIG. 6b is a schematic section view showing another example of plasma CVD electrode having a plasma processing electrode of our invention.

FIG. 7 is a perspective view of a magnetic field analysis model of main body of cathode provided in an embodiment of a plasma electrode of our invention.

FIG. 8 is a sectional side view showing a magnetic field analysis result of the analysis model shown in FIG. 7.

FIG. 9 is a front view showing a magnetic field analysis result of the analysis model shown in FIG. 7.

### DETAILED DESCRIPTION OF EMBODIMENTS OF THE INVENTION

Hereinafter, embodiments of our invention will be explained with reference to the figures, although our invention should not be limited to any embodiment.

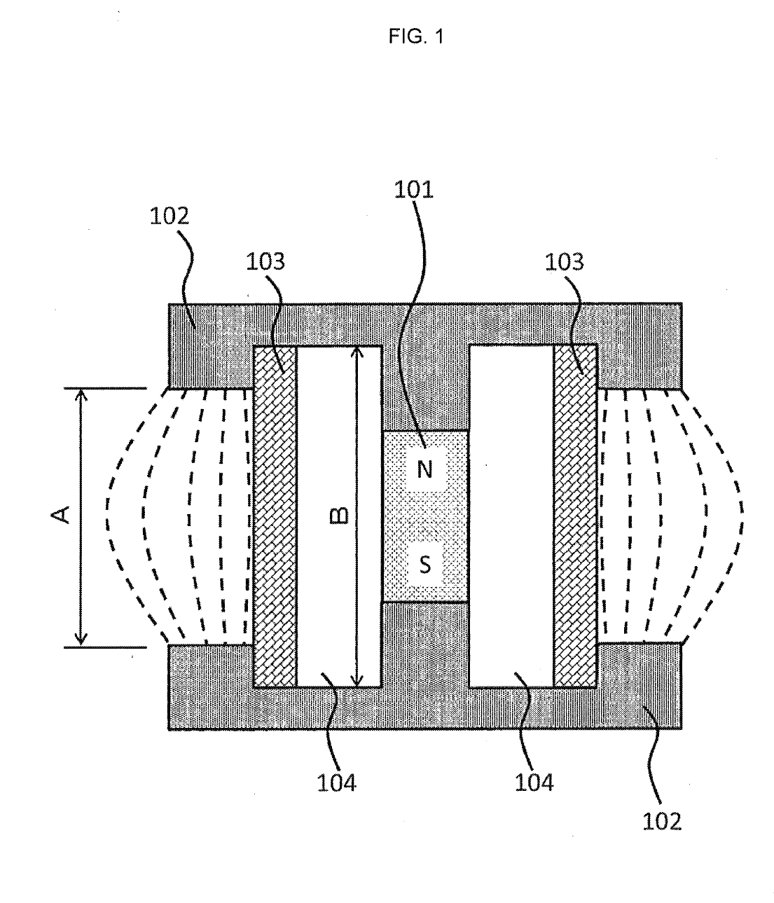

FIG. 1 is a schematic section view showing an example of plasma electrode of our invention. The plasma electrode has a main body of electrode comprising magnet 101, yoke 102 and cathode 103. Magnetic flux generated by magnet 101 is induced by yoke 102 and discharged onto cathode 103, so that magnetic field for magnetron is formed on an electric discharge surface of cathode 103. Cathode 103 is disposed with its surface facing outward while surrounding magnet 101. There are three options of layout in which: (i) one cathode 103 surrounds magnet 101; (ii) a plurality of cathodes 103 surround magnet 101 without each interval and; (iii) a plurality of cathodes 103 surround magnet 101 with each interval. Option (i) is a kind of layout in which cathode 103 is disposed around magnet 103 without any interval. Thus cathode 103 surrounds magnet 101 so that the magnetic field for magnetron formed on the electric discharge surface of cathode 103 is generated continuously to surround the main body of electrode.

The plasma electrode comprises a ground member (not shown) facing cathode 103 with interval. High-density plasma is generated on the surface of cathode 103 by applying electric field between cathode 103 and ground member. The plasma is generated to surround the main body of electrode since the magnetic field for magnetron formed on the electric discharge surface of cathode 103 is generated continuously to surround the main body of electrode as described above. Such a plasma stably connected continuously can prevent troubles, such as plasma generation failure at one side and unbalanced intensity of plasma generated at both sides of the main body of electrode. The ground member may not be disposed to face all cathodes 103, and may be disposed to face some cathodes 103 beyond the main body of electrode. It is preferable that the ground member is disposed to surround the main body of electrode so that plasma generated to surround the main body of electrode is more stable.

The plasma electrode may have refrigerant flow path 104 as a space surrounded by magnetic field generation means 101, yoke 102 and cathode 103. Refrigerant flow path 104 can be cooled off by flowing refrigerant therein to prevent magnet 101 and cathode 103 from being heat damaged with discharge.

Magnet 101 may be designed appropriately in kind and shape so that tunnel-shaped magnetic flux develops on the surface of cathode 103 with sufficient intensity. It is preferable that magnet 101 is a ferrite magnet, a samarium cobalt magnet or a neodymium magnet. Magnet 101 can be formed into a shape corresponding to the shape of electrode. For example, it is preferable that a round-shaped magnet is provided in a small round-shaped electrode. A rectangular magnet may generally be provided in the rectangular electrode. A large magnet with which a wide electrode is provided might have a poor handling ability in assembly work because of its strong magnetic force. In such a case, it is generally preferable that a plurality of rectangular magnets are disposed in a line to form a group of magnets.

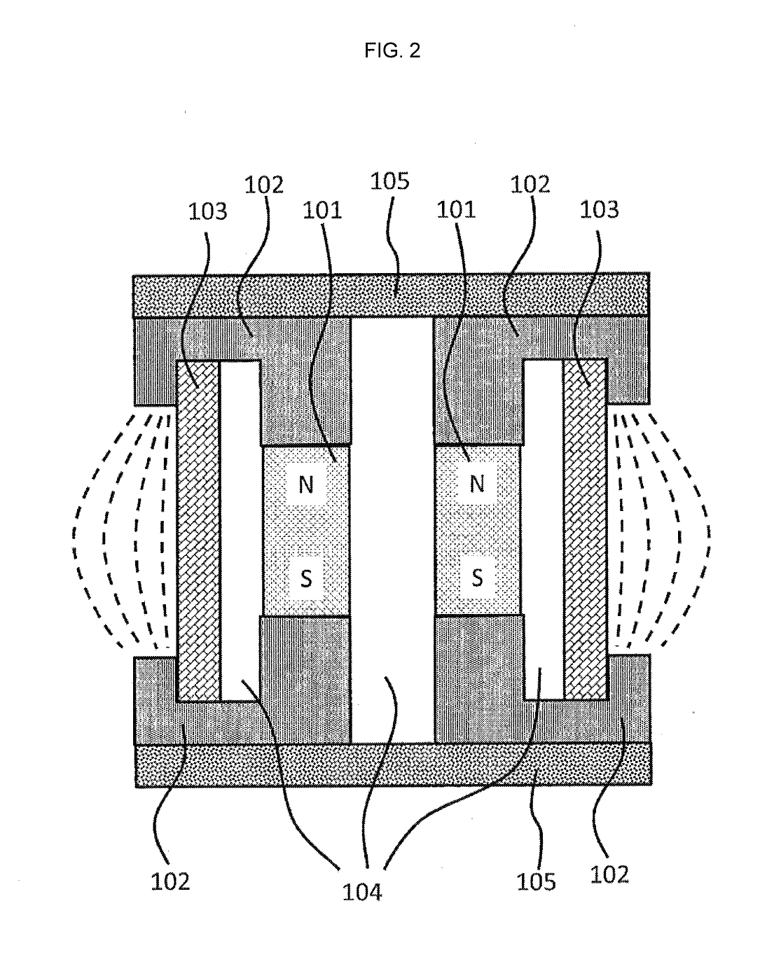

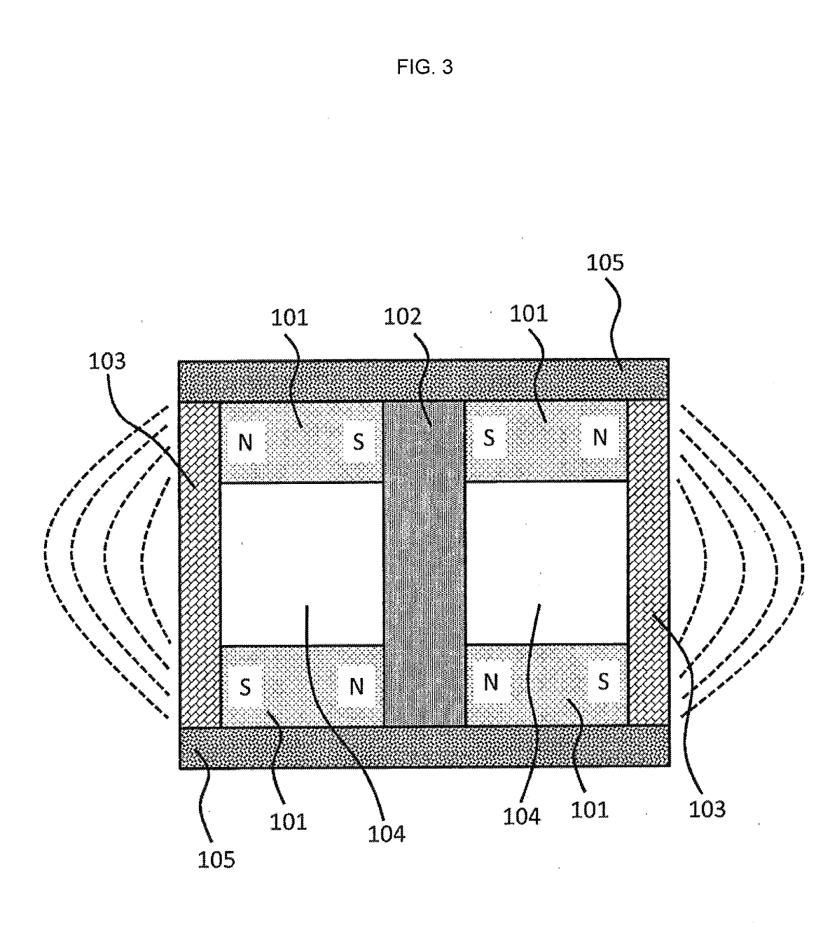

The layout of magnet 101 and yoke 102 can be designed appropriately according to configuration of the magnetic circuit. In a case of magnetic circuit shown in FIG. 1 where magnetic flux discharged from magnet 101 is induced onto the surface of each cathode 103 at both sides with yoke 102, it is preferable that magnet 101 is disposed in the center as shown in FIG. 1. FIG. 2 and FIG. 3 are schematic section views showing other examples of plasma electrode of our invention. In a case of two systems of magnetic circuits shown in FIG. 2 where each magnetic flux discharged from magnet 101 is induced onto the surface of each cathode 103 at one side with yoke 102, it is preferable that each magnet 101 is disposed with respect to each system of magnetic circuit as shown in FIG. 2. In a case of two systems of magnetic circuits shown in FIG. 3 where each magnetic flux discharged from a pair of magnets 101 is induced onto the surface of each cathode 103 at one side, it is preferable that each pair of magnets 101 is disposed with respect to each system of magnetic circuit in two systems of magnetic circuits configured with yoke 102 as shown in FIG. 3.

Cathode 103 may be made of a material selected appropriately according to the use of electrode. For example, when the plasma electrode is intended to be used for a sputtering equipment, it is preferable that cathode 103 has an outermost layer containing a sputtering target material at the electric discharge side. Alternatively, when the plasma electrode is used as a plasma generation source such as ion source, it is preferable that cathode 103 is made of a material such as aluminum and titanium having a low sputtering rate to prevent cathode 103 from eroding with plasma. In both cases, it is preferable that cathode 103 is cooled off with any cooling means, and it is more preferable that cathode 103 in itself is cooled directly with refrigerant.

As shown in FIG. 1 and FIG. 2, an outer side end of yoke 102 can be protruded outer than the surface of cathode 103, which is the electric discharge surface of the main body of electrode, so that the protrusion functions as an auxiliary magnetic pole. It is preferable that such an auxiliary magnetic pole is provided, so that controllability of the magnetic field on cathode 103 is improved. For example, the auxiliary magnetic pole can be designed to generate magnetic field rising up steeply in a narrow span between magnetic poles to generate high-density plasma concentrated in the narrow area. Alternatively, the auxiliary magnetic pole can be designed to generate magnetic field less fluctuating in magnetic field intensity in a wide span between magnetic poles to generate wide plasma. It is preferable to design the magnetic field depending on the purpose of use of the electrode appropriately in this way. In a case of providing the auxiliary magnetic pole, it is preferable that pole span A shown in FIG. 1 is shorter than refrigerant flow path width B. This is because such a configuration can focus the discharge of magnetic flux induced with the yoke as much as possible on the auxiliary magnetic pole.

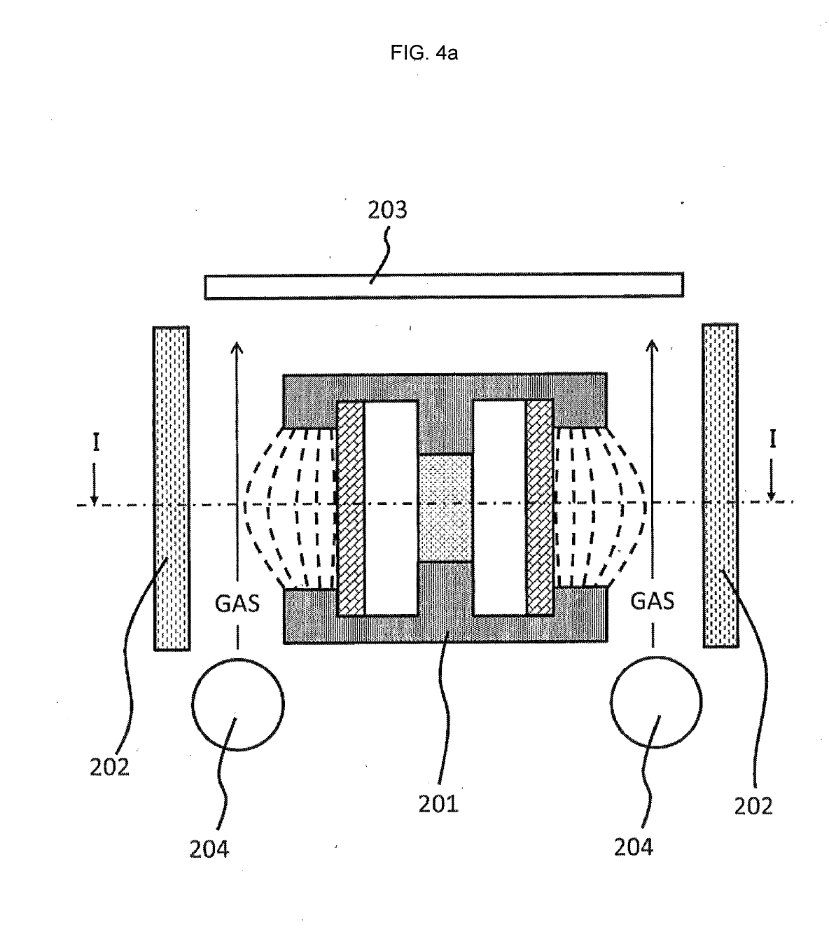

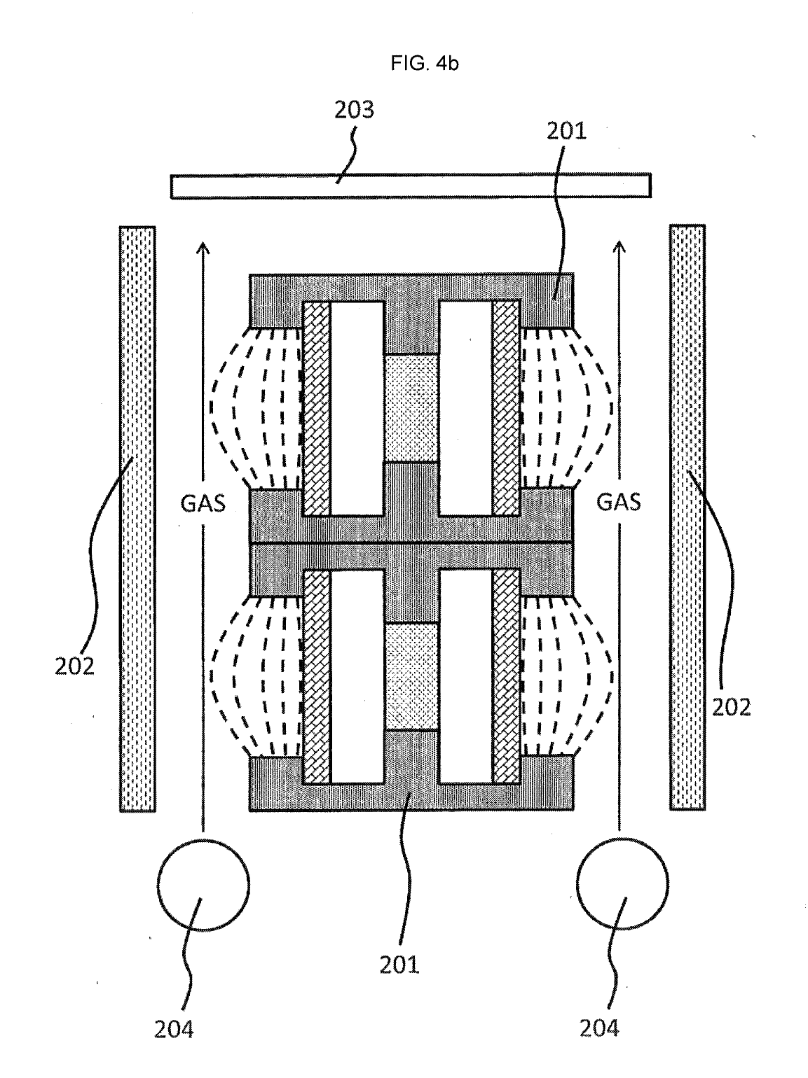

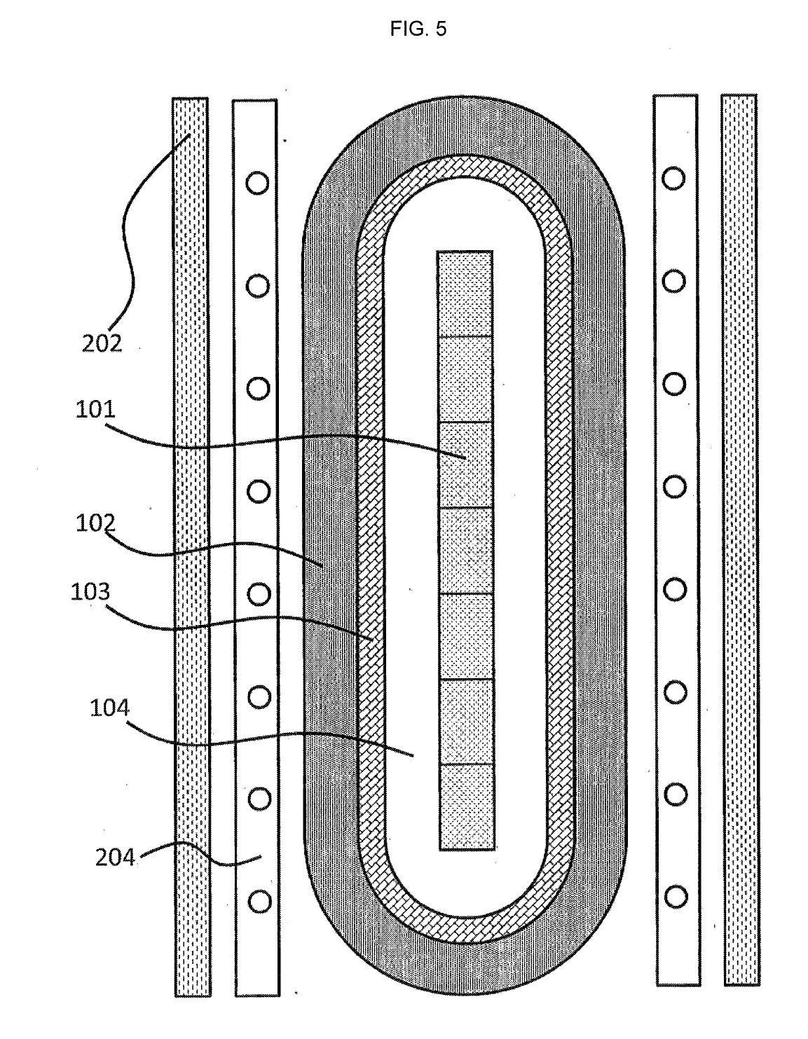

FIG. 4a is a schematic section view showing an example of plasma processing electrode having a plasma electrode of our invention. FIG. 5 is a schematic diagram showing the section viewed in I-I arrow direction of the plasma processing electrode shown in FIG. 4a. This plasma processing electrode is provided with ground members 202 sandwiching electrode 201 as leaving spaces therebetween while electrode 201 is configured as shown in FIG. 1. Further, it is provided with gas nozzles 204 which introduce gas in a direction parallel to the electric discharge surface of cathode 103 between the electric discharge surface and ground members 202. Substrate 203 is supported by a supporting mechanism (not shown) in a position distant from electrode 201 on a line (gas downstream side) extended along the gas introduction direction of gas nozzle 204 and is processed on its surface with plasma. The supporting mechanism of substrate may be fixed or movable to convey substrate 203 through a cylindrical drum shaped body.

Gas nozzle 204 is provided to introduce gas directly into a space ionized by electrode 201 so that the introduced gas is ionized efficiently. In addition, it can orient the gas introduction flow so that ion and radical generated in the ionized space are utilized efficiently. It is therefore preferable that the plasma processing electrode is provided in a plasma processing device such as ion source and radical source, and is preferably provided in a plasma CVD electrode.

FIG. 4b is a schematic section view showing another example of plasma processing electrode having the plasma electrode of our invention. This plasma electrode unit comprises two basic units of electrode 201 shown in FIG. 1 disposed along the flow direction of gas introduced from gas nozzle 204. With such disposed two basic units, the introduced gas is exposed for a long time by high density plasma and resolved acceleratingly. Thus increasingly produced ion and radical contribute to the improvement in processing performance of plasma processing device and film deposition speedup of plasma CVD device. Further, three or more basic units may be disposed in the plasma processing electrode although only two basic units are disposed in FIG. 4b.

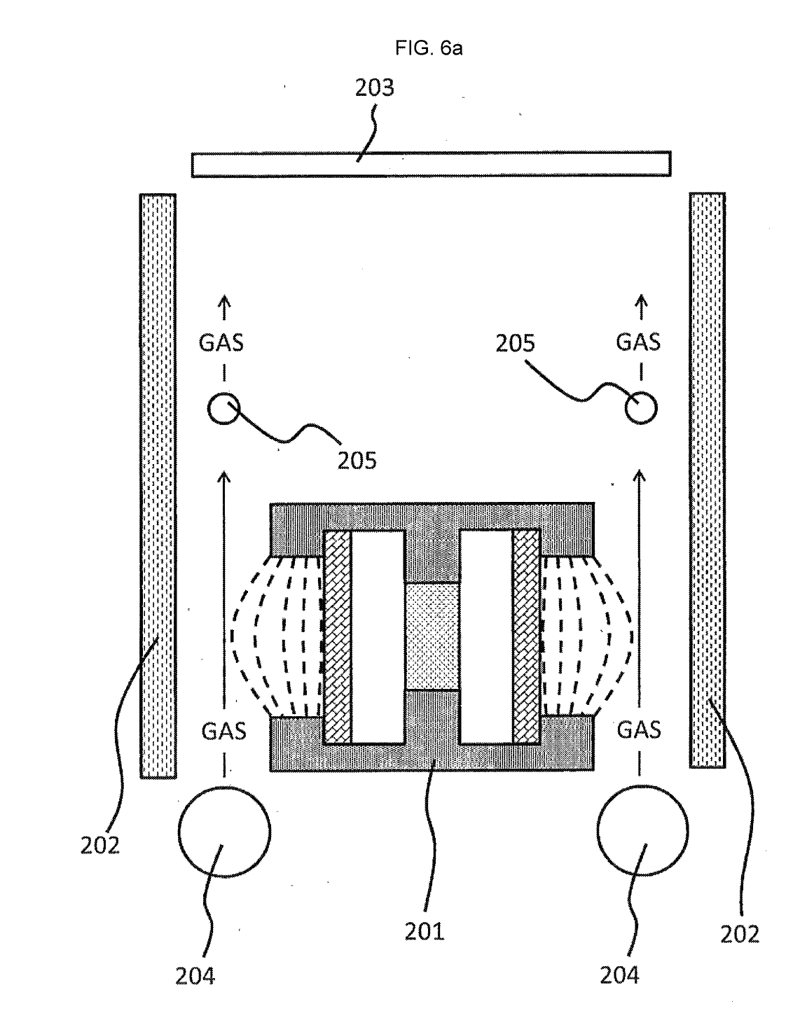

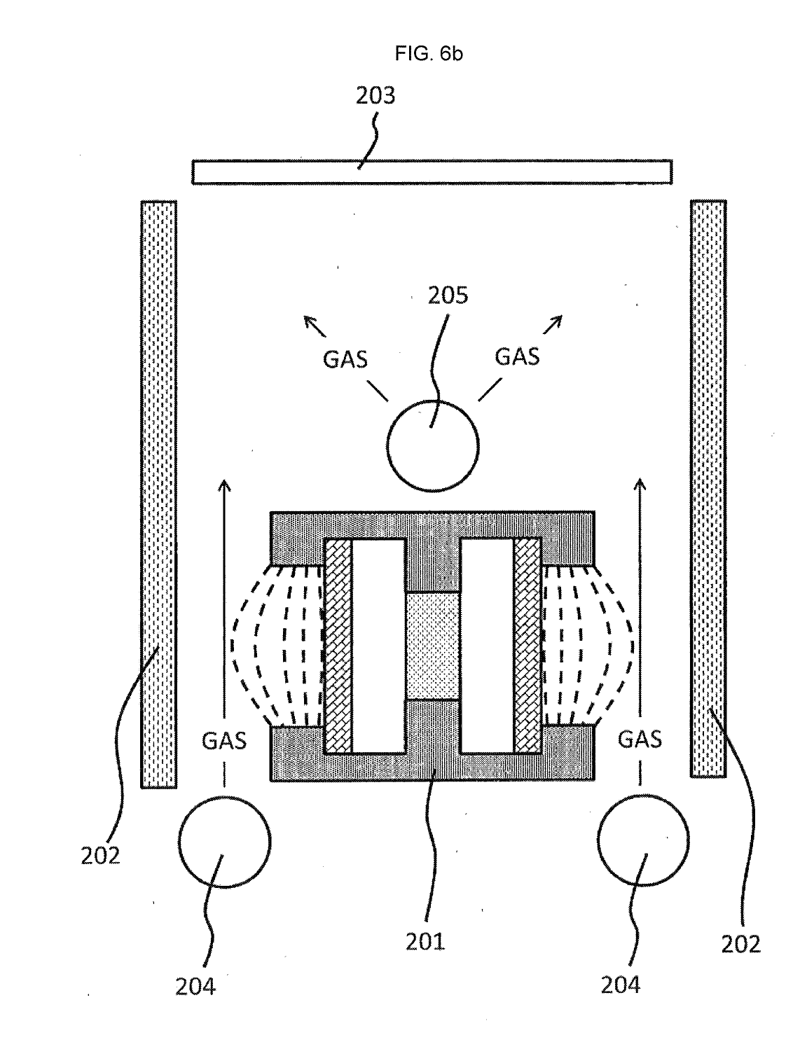

FIG. 6a is a schematic section view showing an example of plasma CVD electrode having the plasma processing electrode of our invention. In addition to the configuration of plasma processing electrode shown in FIG. 4a, source gas nozzles 205 to feed CVD source gases are further provided opposite to gas nozzle 204 from the electric discharge space. Using this plasma processing electrode, plasma is generated with a plasma electrode in the electric discharge space. Gas is introduced through gas nozzle 204 toward the electric discharge space and ionized. The ionized gas is fed onto substrate 203 while CVD source gases are fed onto substrate 203 through source gas nozzle 205, so that the CVD gases are resolved to deposit a thin film on substrate 203.

FIG. 6b is a schematic section view showing another example of plasma CVD electrode having the plasma processing electrode of our invention. In addition to the configuration of plasma processing electrode shown in FIG. 4a, source gas nozzle 205 to feed CVD source gases is further provided in a space between the main body of electrode 201 and substrate 203. Using this plasma processing electrode, plasma is generated with a plasma electrode in the electric discharge space. Gas is introduced through gas nozzle 204 toward the electric discharge space and ionized. The ionized gas is fed into the space between the main body of electrode 201 and substrate 203 while CVD source gases are fed into the space through source gas nozzle 205, so that the CVD gases are resolved to deposit a thin film on substrate 203.

The plasma CVD electrodes shown in FIG. 6a and FIG. 6b are provided with source gas nozzle 205 downstream of basic gas flow from the electric discharge space, so that film depositing seeds are prevented from flowing back and electrode 201 is prevented from being contaminated. Further, substrate 203 can be kept away from the electric discharge space so that a film deposition is performed with less damage by preventing the thermal damage and ion bombardment caused by plasma. From a viewpoint of easy handling of components such as source gas nozzle 205, it is preferable that a minimum distance between the center of the electric discharge space and substrate 203 is 30 mm or more. When the distance between the center of the electric discharge space and substrate 203 is longer than 300 mm, the film depositing rate might be deteriorated to increase the occupied space and decrease efficiency. Therefore it is preferable that the distance is 300 mm or less.

To remove charged particles damaging the substrate and deposited film, it is preferable that an electrically-grounded mesh conductor is provided between electrode 201 and a position to place substrate 203. To prevent the film depositing ability from deteriorating by blocking the passage of products other than the charged particles, it is preferable that the mesh opening rate is 50% or more.

### Example

Hereinafter, magnetic circuit analysis results of the plasma electrode described above will be shown as follows.

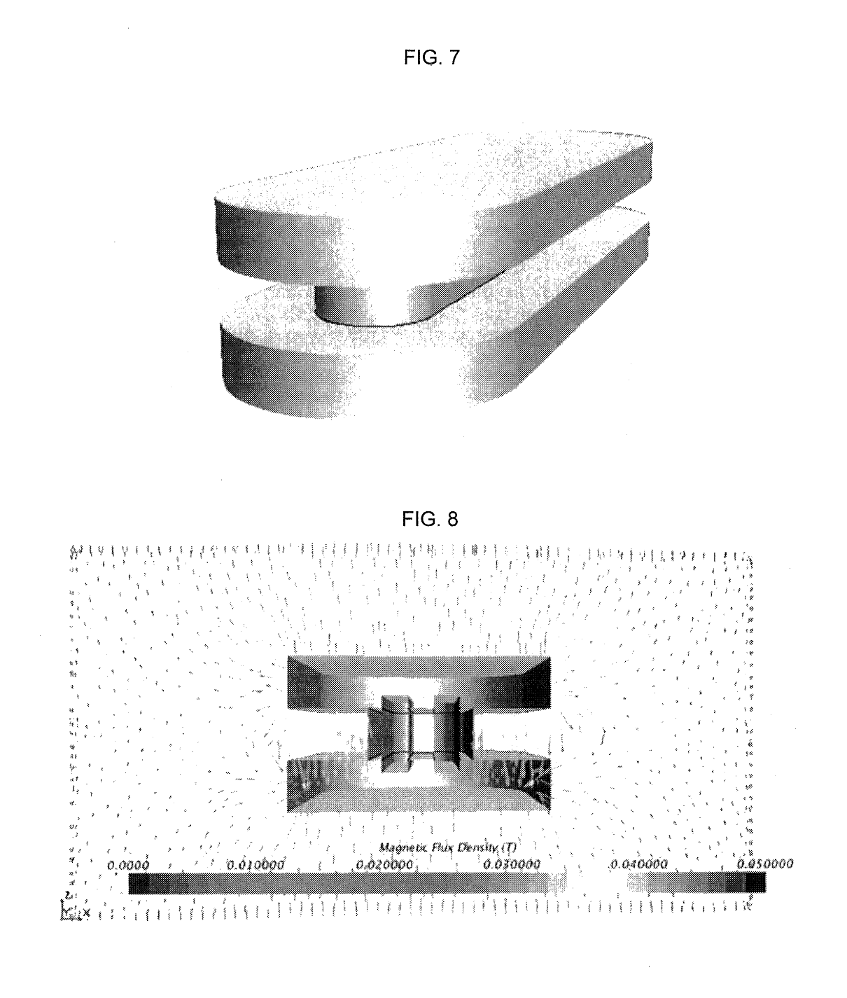

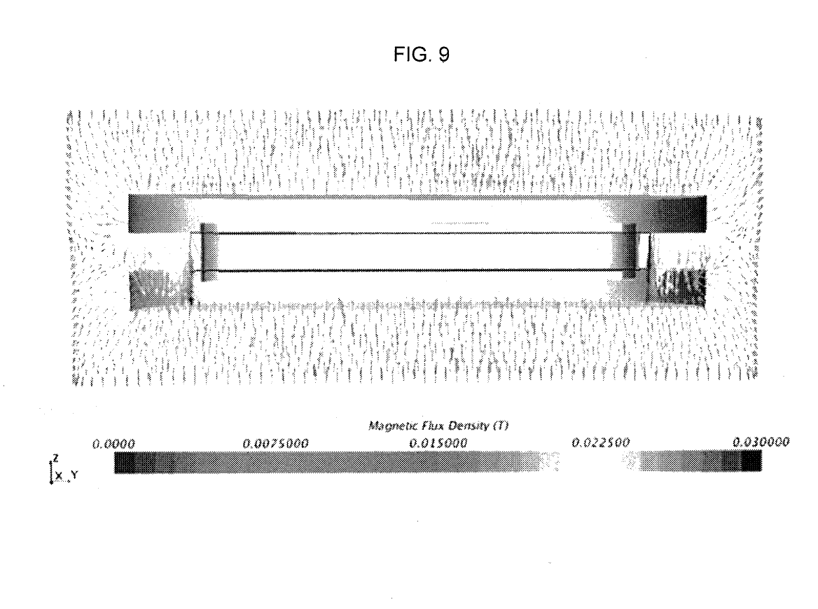

The main body of electrode shown in FIG. 1 was employed. The analysis was performed under an assumption such that magnet 101 comprises neodymium magnets each having a size of 20 mm in height (in the magnetization direction), 10 mm in width and 40 mm in length and that the magnet surface magnetic flux density is 300 mT. It was also assumed that yoke 102 is made of ferrite-based stainless steel SUS430 and specific magnetic permeability is 500 (absolute magnetic permeability of 1.26×10⁻⁶×500 H/m). It is further assumed that cathode 103 is made of pure titanium and coolant water flows in refrigerant flow path 104. The analysis model shown in FIG. 7 was analyzed with STAR-CCM+Ver.7.04.011 under the above-described assumption. The result of analysis showed that a tunnel-shaped magnetic flux is formed to surround a cathode. FIG. 8 and FIG. 9 show the magnetic flux density distribution. Such a cathode can generate plasma which is stable enough to prevent the plasma intensity from being greatly different between both linear sections.

Our invention is applicable to plasma CVD electrode, plasma processing electrode, and plasma electrode as ion source or radical source, although these applications do not limit our invention.

### EXPLANATION OF SYMBOLS

101: magnet
102: yoke
103: cathode
104: refrigerant flow path
105: casing
201: electrode
202: ground member
203: substrate
204: gas nozzle
205: source gas nozzle
A: pole span
B: refrigerant flow path width

1. A plasma electrode having an electrode main body and ground members, the electrode main body comprising: a discharge surface on an outer circumference surface thereof and; a magnet provided inside for forming a tunnel-shaped magnetic field on the discharge surface, the ground members facing at least a portion of the discharge surface with a gap therebetween and facing each other so as to sandwich the electrode main body therebetween, the discharge surface surrounding the outer circumference surface of the electrode main body, either with or without a gap interposed therebetween.

2. The plasma electrode according to claim 1, further comprising an auxiliary magnetic pole of which outer side end is protruded outer than the electric discharge surface of the electrode main body.

3. The plasma electrode according to claim 1, wherein the ground member surrounds the electrode main body.

4. A plasma processing electrode comprising the plasma electrode according to claim 1 and a gas nozzle introducing a gas in a direction parallel to the electric discharge surface into an electric discharge space between the ground member and the electric discharge surface facing the ground member.

5. (canceled)

6. A CVD electrode comprising the plasma processing electrode according to claim 4 and a source gas nozzle introducing a CVD source gas into a neighborhood of the electrode main body, wherein a film is deposited on a substrate placed in a position which is distant from the electrode main body and is downstream in a flow direction of the gas discharged from the gas nozzle.

7. The CVD electrode according to claim 6, wherein the source gas nozzle is provided opposite to the gas nozzle with respect to the electric discharge space.

8. The CVD electrode according to claim 6, wherein the source gas nozzle is provided in a space between the electrode main body and the position to place the substrate.

9. The CVD electrode according to claim 6, wherein a minimum distance between the position to place the substrate and the electrode main body is 30 mm or more and 300 mm or less.

10. The CVD electrode according to claim 6, wherein an electrically-grounded mesh having an opening rate of 50% or more is provided between the electrode main body and the position to place the substrate.

11. A plasma CVD device, comprising the CVD electrode according to claim 6 and a supporting mechanism of the substrate in a vacuum chamber.

12. A manufacturing process of a substrate with a thin film comprises: a plasma generation step to generate a plasma with the plasma electrode of the CVD electrode according to claim 6; a gas feeding step to resolve the gas introduced through the plasma from the gas nozzle and feed a radical generated onto the substrate; a CVD source gas feeding step to feed the CVD source gas introduced from the source gas nozzle onto the substrate to deposit a thin film on the substrate.
